(19) United States
(12) Patent Application Publication
(10) Pub. No.: US 2013/0256558 A1
(43) Pub. Date: Oct. 3, 2013

(54) APPARATUS FOR CONTAMINANTS BEING DEPOSITED THEREON

(71) Applicants: Christian DIETL, Aalen (DE); Gerald SCHMID, Blaustein (DE); Bernd SCHINDLER, Aalen (DE); Gerd BENNER, Aalen (DE); Thilo MANDLER, Oberkochen (DE); Marco MATIJEVIC, Nurtingen (DE)

(72) Inventors: Christian DIETL, Aalen (DE); Gerald SCHMID, Blaustein (DE); Bernd SCHINDLER, Aalen (DE); Gerd BENNER, Aalen (DE); Thilo MANDLER, Oberkochen (DE); Marco MATIJEVIC, Nurtingen (DE)

(21) Appl. No.: 13/433,748

(22) Filed: Mar. 29, 2012

(51) Int. Cl. B01D 53/22; H01J 37/02

(52) U.S. Cl. 250/440.11; 96/221

(57) ABSTRACT

An apparatus for contaminants being deposited thereon in a particle beam device, and also the particle beam device including the apparatus, are provided. This apparatus may be an anticontaminator. The apparatus according to the system described herein may include at least one cooling unit. The cooling unit may provide at least one cooled surface on which contaminants in a particle beam device are deposited. The apparatus according to the system described herein may further include at least one aperture unit. The aperture unit may be arranged at a motion device for moving the aperture unit relative to the cooling unit. Furthermore, the aperture unit may have at least one aperture opening. The cooling unit may be connected to the aperture unit by at least one first flexible thermal conductor.

### TECHNICAL FIELD

This application relates to an apparatus for contaminants being deposited thereon in a particle beam device. This application also relates to a particle beam device comprising an apparatus for contaminants being deposited thereon.

### BACKGROUND OF THE INVENTION

Electron beam devices, in particular a scanning electron microscope (also referred to hereinafter as SEM) and/or a transmission electron microscope (also referred to hereinafter as TEM), are used to examine objects (samples) in order to obtain knowledge about the characteristics and behaviour of objects in specific conditions.

In the case of an SEM, an electron beam (also referred to as a primary electron beam) is generated using a beam generator and, using a beam guidance system, is focused onto an object to be examined. The primary electron beam is guided in a raster shape over a surface of the object to be examined using a deflection device. The electrons in the primary electron beam interact with the object to be examined. As a consequence of the interaction, in particular electrons are emitted from the surface of the object to be examined (so-called secondary electrons) and electrons in the primary electron beam are scattered back (so-called back-scattered electrons). The secondary electrons and back-scattered electrons are detected and are used for image production. An image of the surface of the object to be examined is thus obtained.

Furthermore, it is known from the prior art to use an ion beam for examining an object. An ion beam generator which is arranged in an ion beam column is used to generate ions which are used for preparation of an object (for example etching of the object or deposition of material on the object), or else for imaging.

In the case of a TEM, a primary electron beam is likewise generated using a beam generator and is guided to an object to be examined using a beam guidance system. The primary electron beam passes through the object to be examined. When the primary electron beam passes through the object to be examined, the electrons in the primary electron beam interact with the material of the object to be examined. The electrons passing through the object to be examined are imaged onto a phosphor screen using a system comprising an objective and a projection lens, or are detected by a position-resolving detector (for example a camera). In the scanning mode of a TEM, as in an SEM, the primary electron beam of the TEM is focused on the object to be examined, and is guided in a raster shape over the object to be examined, using a deflection device. The transmitted (highly) scattered electrons are analyzed by a detector. A TEM such as this is generally referred to as an STEM. For analyzing the object, it is also possible to use X-rays emitted from the object to be examined and/or back scattered electrons scattered from the object to be examined, using a further detector to detect them.

For some objects, for example biological objects, it is sometimes desirable to examine them at a low temperature, for example in the vicinity of the temperature of liquid nitrogen or liquid helium. Therefore, an object holder holding an object to be examined is provided with a cooling device for cooling the object.

It is also known to provide a TEM with a device for minimizing the deposition of contaminants such as carbon, hydrocarbon or water which may condense on the object and may blur the details of the object. Such a device is known as an anticontaminator. A known anticontaminator comprises a dewar of liquid nitrogen mounted on the side of a TEM. A thermal conductor is connected to a cold shield onto which blades are mounted which surround the object. The anticontaminator is arranged in the vicinity of an object to be examined. Any contaminants are deposited on it, so that the object to be examined is not contaminated. Moreover, the object to be examined is arranged in a chamber of the TEM which is evacuated so that a specific vacuum may be reached. The anticontaminator is used for improving the vacuum in the area of the object to be examined.

Reference is made to documents U.S. Pat. No. 4,833,330, EP 1 102 304 A2, DE 103 44 492 A1, EP 1 852 889 A2, EP 1 351 271 A1 and U.S. Pat. No. 4,179,605, which are all incorporated herein by reference.

Deliberations have revealed that it is desirable to provide an anticontaminator which is movable so that it may be arranged in a position in the vicinity of an object to be examined, thus providing for sufficient deposition of contaminants on the anticontaminator, and, thereby preventing contaminants from being deposited on the object to be examined. Moreover, it is desirable to provide an anticontaminator being sufficiently cooled to achieve the above mentioned effects with respect to the improvement of the vacuum.

### SUMMARY OF THE INVENTION

According to the system described herein, an apparatus for contaminants being deposited thereon in a particle beam device is provided. This apparatus may be an anticontaminator. The apparatus according to the system described herein may include at least one cooling unit. The cooling unit may provide at least one cooled surface on which contaminants in a particle beam device are deposited. Furthermore, the apparatus according to the system described herein may include at least one aperture unit. The aperture unit may be arranged at a motion device for moving the aperture unit. Furthermore, the aperture unit may have at least one aperture opening. The cooling unit may be connected to the aperture unit by at least one first flexible thermal conductor.

Deliberations have revealed that the apparatus may provide for a movement of the aperture unit so that it may be arranged in a position in the vicinity of an object to be examined, for example in a particle beam device, so that most of the contaminants are deposited on the anticontaminator. A particle beam is able to pass through the aperture opening and is guided to the object to be examined. The aperture opening may define a beam diameter of a particle beam transmitting through the object. The aperture unit may be arranged next to the object to be examined, preferably near the focal plane of the objective lens, and may also be provided for depositing contaminants which should not be deposited on the object.

Since the cooling unit may be connected to the aperture unit by a flexible thermal conductor, it has been revealed that (i) the aperture unit is sufficiently cooled so that contaminants may be deposited on the aperture unit and that (ii) the aperture unit may be positioned by the motion device as desired.

In an embodiment of the system described herein, it is additionally or alternatively provided that the cooling unit is exclusively connected to the aperture unit by the at least one first thermal conductor, and that the cooling unit is otherwise entirely spatially separated from the aperture unit.

In a further embodiment of the system described herein, it is additionally or alternatively provided that the apparatus comprises at least one of the following features: (i) the aperture unit is movable along at least one first translational axis, (ii) the aperture unit is movable along at least one second translational axis, (iii) the aperture unit is movable along at least one third translational axis, and (iv) the aperture unit is rotatable around at least one rotational axis. The motion device may be provided to move the aperture unit along one of the aforementioned translational axes or around the aforementioned rotational axis.

In a further embodiment of the system described herein, it is additionally or alternatively provided that at least one thermal isolator is arranged between the aperture unit and the motion device. This way, the temperature of the aperture unit, which is generated by a heat transfer from the aperture unit to the cooling unit, stays the same or nearly the same.

In another embodiment of the system described herein, it is additionally or alternatively provided that the cooling unit comprises at least one cooling surface for contaminants being deposited thereon. Moreover, the cooling surface may be connected with a cooling device. The cooling device comprises a container for holding a cooling solvent. In this embodiment, the cooling device provides for the cooling of the cooling unit and, therefore, also the aperture unit. The cooling unit and the cooling device may be separated from each other and may be two discrete elements of the apparatus. They may be connected to each other by a thermal conductor.

In another embodiment of the system described herein, it is additionally or alternatively provided that the cooling unit comprises at least one first cooling surface unit and at least one second cooling surface unit. The first cooling surface unit is connected to a cooling device, for example using a thermal conductor. The cooling device comprises a container for holding a cooling solvent. The cooling unit and the cooling device of this embodiment may also be separated from each other and may be two discrete elements of the apparatus. In this embodiment, the cooling device also provides for the cooling of the cooling unit and, therefore, also the aperture unit. The cooling surface and the cooling surface units, respectively, are used for contaminants being deposited thereon.

In another embodiment of the system described herein, it is additionally or alternatively provided that the cooling solvent is a cryogen, for example liquid nitrogen or liquid helium. However, it is explicitly mentioned that the system described herein is not restricted to a cooling solvent as mentioned above. Any suitable cooling solvent, solid coolant and/or mixture of a liquid coolant and a solid coolant can be used for the system described herein.

In a further embodiment of the system described herein, it is additionally or alternatively provided that the cooling unit is connected to the aperture unit additionally by at least one second flexible thermal conductor. This flexible thermal conductor achieves the same effects as mentioned above with respect to the first thermal conductor.

In another embodiment of the system described herein, it is additionally or alternatively provided that the apparatus according to the system described herein comprises at least one of the following features: (i) the first flexible thermal conductor is a braided tape, and (ii) the first flexible thermal conductor is a copper conductor. Deliberations have revealed that a braided tape, in particular a copper conductor, may be used as the first flexible thermal conductor due to its flexibility and heat transfer capacity. It is explicitly mentioned that the apparatus according to the system described herein is not restricted to a copper conductor. Instead, any suitable conducting material may be used, for example silver, gold, beryllium or a carbon composite. Moreover, the system described herein is not restricted to a braided tape as the first flexible thermal conductor. Instead, the first flexible thermal conductor may have any suitable form. In a further embodiment, the first flexible thermal conductor may be shaped as a compound spring.

In a further embodiment of the system described herein, it is additionally or alternatively provided that the apparatus according to the system described herein comprises at least one of the following features: (i) the second flexible thermal conductor is a braided tape, and (ii) the second flexible thermal conductor is a copper conductor. As mentioned for the first thermal conductor, these embodiments are advantageous due to various reasons. The flexibility of the second flexible thermal conductor is advantageous with respect to the movement of the aperture unit. Deliberations have revealed that a braided tape, in particular a copper conductor, may be used as the second flexible thermal conductor due to its flexibility and heat transfer capacity. It is explicitly mentioned that the second flexible thermal conductor is not restricted to a copper conductor. Instead, any suitable conducting material may be used, for example silver, gold, beryllium or a carbon composite. Moreover, the system described herein is not restricted to a braided tape as the second flexible thermal conductor. Instead, the second flexible thermal conductor may have any suitable form. In a further embodiment, the second flexible thermal conductor may be shaped as a compound spring.

In another embodiment of the system described herein, it is additionally or alternatively provided that the apparatus comprises more than two flexible thermal conductors, for example three flexible thermal conductors. The system described herein is not restricted to any particular number of flexible thermal conductors. Instead, any suitable number of flexible thermal conductors may be used.

In a further embodiment of the system described herein, it is additionally or alternatively provided that the first flexible thermal conductor and/or the second flexible thermal conductor is/are arranged at the aperture unit in an area which is in the vicinity of an object to be examined (for example, 5 mm to 30 mm, in particular 15 mm to 25 mm from the object to be examined). This provides for a good cooling of the aperture unit in an area which is close to the object to be examined. Contaminants are readily deposited in that area and will not be deposited on the object to be examined.

In another embodiment of the system described herein, it is additionally or alternatively provided that the aperture unit comprises several parts, in particular at least one first aperture device and at least one second aperture device. The first aperture device may be arranged close to a first pole piece (upper pole piece) and may have at least one first aperture opening, and the second aperture device may be arranged close to a second pole piece (lower pole piece) and may have at least one second aperture opening. The first aperture device may be separated from the second aperture device. For example, the first aperture device is arranged relative to the second aperture device in a step like manner. At least one of the above mentioned aperture openings may be provided to accommodate at least one aperture element being suitable for field limiting electron optical purposes and/or aperture limiting electron optical purposes on or in the aperture opening.

In a further embodiment of the system described herein, it is additionally or alternatively provided that the apparatus comprises one of the following features: (i) the first aperture opening is an aperture for imaging of an object with a particle beam, (ii) the second aperture opening is an aperture for imaging of an object with a particle beam, (iii) the first aperture opening is an aperture for illuminating an object with a particle beam, and (iv) the second aperture opening is an aperture for illuminating an object with a particle beam. The aperture for imaging may be an aperture for impacting the contrast of an image of an object to be examined using a particle beam. The aperture for illuminating is used for illuminating the object with a particle beam. It may be used for impacting the beam convergence of a particle beam used and for reducing stray electrons. The particle beam is used, for example, for EDX measurements (energy dispersive X-ray spectroscopy) or measurements by scanning a particle beam over an object to be examined.

In a further embodiment, the apparatus comprises only the aperture openings provided by the aperture unit for reducing contamination on the object to be examined. No further aperture is used in this embodiment.

In a further embodiment of the system described herein, it is additionally or alternatively provided that the aperture unit is made from a material having an atomic number less than 13. For example, the aperture unit comprises beryllium or is made of beryllium. This embodiment is provided, in particular, when an object is examined by EDX (energy dispersive X-ray spectroscopy). An aperture unit comprising a material having an atomic number less than 13, in particular beryllium, avoids generating undesired X-rays when a particle beam hits the aperture unit. The EDX measurements of the object are therefore more accurate. It is explicitly mentioned that the material of the aperture unit is not restricted to beryllium or any other material having an atomic number less than 13. Instead, any suitable material may be used, for example titanium or aluminium. The cooling unit may also be made from a material having an atomic number less than 13. For example, the cooling unit comprises beryllium or is made of beryllium. The cooling unit may have an opening for arranging an EDX detector into the opening and may be used as a collimation device so that only X-rays generated in the object to be examined will be detected by the EDX detector.

In another embodiment of the system described herein, it is additionally or alternatively provided that the apparatus according to the system described herein comprises at least one heating device which is used to heat the cooling unit and, therefore, the aperture unit. This is sometimes desirable when it comes to removing contaminants deposited on the cooling unit and/or the aperture unit. For example, those contaminants are removed by a pumping system.

The system described herein may also relate to a particle beam device. The particle beam device may include at least one beam generator for generating a particle beam, at least one holding element for holding an object and at least one objective lens for imaging or focusing the particle beam. Moreover, the particle beam device may include an apparatus (anticontaminator) having at least one of the above mentioned or below mentioned features or at least a combination of two of the above mentioned or below mentioned features. For example, the apparatus may be arranged in the objective lens.

In another embodiment of the particle beam device described herein, it is additionally or alternatively provided that the particle beam device comprises one of the following features: (i) the motion device is arranged at a flange (for example, the motion device is guided in the flange), wherein the flange is arranged on a vacuum chamber of the particle beam device, (ii) the aperture unit and the motion device are arranged at a flange (for example, the aperture unit is arranged at the motion device, and the motion device is guided in the flange), wherein the flange is arranged on a vacuum chamber of the particle beam device, (iii) the cooling unit and the motion device are arranged at a flange on a vacuum chamber of the particle beam device (for example the cooling unit is mounted at the flange and the motion device is guided in the flange), and (iv) the cooling unit, the motion device and the aperture unit are arranged at a flange at a vacuum chamber of the particle beam device. The cooling unit may be connected to a cooling device by a thermal conductor, as mentioned above. The embodiments provide that the motion device, the aperture unit and/or the cooling unit may be mounted on the particle beam device in a single step by arranging the flange on the vacuum chamber of the particle beam device.

In a further embodiment of the particle beam device described herein, it is additionally or alternatively provided that the particle beam device comprises a cooling system for cooling an object to be examined. The cooling system may comprise a container for holding a cooling solvent. The cooling solvent may be a cryogen, for example liquid nitrogen or liquid helium. However, it is explicitly mentioned that the system described herein is not restricted to a cooling solvent as mentioned above. Any suitable cooling solvent can be used for the system described herein.

In another embodiment of the particle beam device described herein, it is additionally or alternatively provided that the particle beam device is an electron beam device (for example a TEM or an SEM) or an ion beam device.

### BRIEF DESCRIPTION OF THE DRAWINGS

Embodiments of the system described herein are explained in greater detail below on the basis of the figures, which are briefly described as follows:

FIG. 1 shows a schematic illustration of a particle beam device in the form of a TEM according to an embodiment of the system described herein;

FIG. 2 shows a schematic illustration of an area of an object plane of the particle beam device according to FIG. 1;

FIG. 3 shows a first schematic view of a pole piece area of an objective lens of a particle beam device according to an embodiment of the system described herein;

FIG. 4 shows a second schematic view of a pole piece area of an objective lens of a particle beam device according to an embodiment of the system described herein;

FIG. 5 shows a third schematic view of a pole piece area of an objective lens of a particle beam device according to an embodiment of the system described herein; and

FIG. 6 shows a fourth schematic view of a pole piece area of an objective lens of a particle beam device according to an embodiment of the system described herein.

### DETAILED DESCRIPTION OF VARIOUS EMBODIMENTS

The system described herein is now described with respect to a TEM. However, the system described herein is not restricted to a TEM. Instead, in other embodiments, the system described herein may also related to any other particle beam device, in particular an ion beam device or an SEM, or a combination of an ion beam device and an SEM.

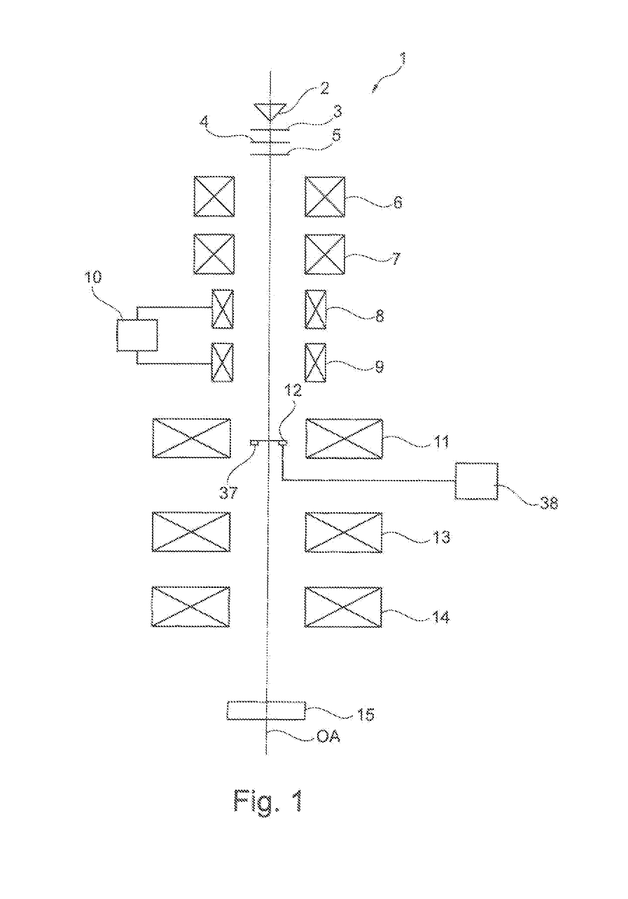

FIG. 1 shows a schematic illustration of a particle beam device 1 which is designed as a TEM according to an embodiment of the system described herein. The particle beam device 1 has an electron source 2 in the form of a thermal field emission source. However, a different particle beam source may also be used. An extraction electrode 3 is arranged behind the electron source 2 along the optical axis OA of the particle beam device 1, and the potential on this extraction electrode 3 extracts electrons from the electron source 2. Furthermore, a first electrode 4 is provided for focusing the source position, and at least one second electrode 5 in the form of an anode is provided for accelerating the electrons. Due to the second electrode 5, the electrons emerging from the electron source 2 are accelerated to a desired and adjustable energy by an electrode voltage. The electrons form a particle beam in the form of an electron beam.

At least one two-stage condenser arranged further on the optical axis OA has a first magnetic lens 6 and a second magnetic lens 7, and a first raster device 8 and a second raster device 9 are connected downstream of the condenser. Both the first raster device 8 and the second raster device 9 are connected to a first control unit 10. The first control unit 10 is provided with a control processor which produces control signals. The first raster device 8 and the second raster device 9 can be used to scan the particle beam over an object which is arranged on an object plane 12. Furthermore, the particle beam device 1 has an objective lens 11, which is in the form of a magnetic lens. The object plane 12 is arranged at the objective lens 11, and the object to be examined is arranged on the object plane 12.

In the direction opposite to the electron source 2, the objective lens 11 is followed by a projection lens system having at least a first lens 13 and at least a second lens 14. The first lens 13 and the second lens 14 then produce a representation on a detector 15 of the object which is arranged on the object plane 12. The representation is, for example, an image or a diffraction pattern of the object.

The particle beam device 1 comprises a vacuum system. The path along the optical axis OA of the particle beam device 1 is evacuated by a pumping system. A vacuum of 1×10⁻⁹ Pa to 1×10⁻⁹ Pa may be achieved. However, the system described herein is not restricted to this vacuum. Instead, any suitable vacuum may be chosen.

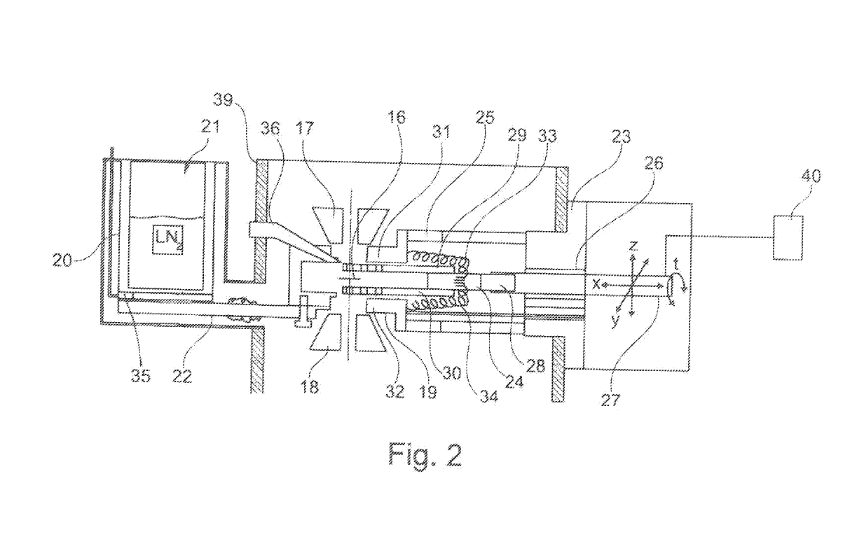

FIG. 2 shows a schematic illustration of the area of the object plane 12 comprising an object 16. The object 16 may be arranged at an object holder 37 which is schematically shown in FIG. 1 and which is connected to a cooling system 38 for cooling the object 16. The cooling system 38 may have a dewar comprising liquid nitrogen or liquid helium. However, any other suitable cooling solvent may be used and any suitable cooling temperature may be chosen. The object 16 may be cooled to a temperature sufficient for an examination of the object 16. The object 16, for example, may be a biological sample.

The object 16 is arranged in the objective lens 11. More precisely, the object 16 is arranged between a first pole piece 17 and a second pole piece 18 of the objective lens 11 in an area where a magnetic field for focusing and imaging is provided. A cooling unit 19 is also arranged between the first pole piece 17 and the second pole piece 18. Moreover, the particle beam device 1 comprises a cooling device 20 being separated from the cooling unit 19. In other words, the cooling unit 19 and the cooling device 20 are separate units of the particle beam device 1. However, in further embodiments, the cooling unit 19 and the cooling device 20 may be combined to a single unit.

In the embodiment of FIG. 2, the cooling unit 19 is connected to the cooling device 20 by a thermal conductor 22 for providing a heat exchange between the cooling device 20 and the cooling unit 19. The cooling device 20 comprises a dewar 21. The dewar 21 may contain a cooling solvent, for example liquid nitrogen or liquid helium. However, as mentioned above, any other suitable cooling solvent may be used. The dewar 21 comprises a bottom which is cooled by vaporizing the cooling solvent. The bottom of the dewar 21 is attached to the thermal conductor 22. Due to a heat exchange between the cooling device 20 and the cooling unit 19 via the thermal conductor 22, the cooling unit 19 is cooled to or nearly to the temperature of cooling solvent. The thermal conductor 22 may be a flexible braided thermal conductor made of copper or a similar material, having a high thermal conductance.

The cooling unit 19 is also arranged at a holding element 23 which is arranged at a particle beam column 39 of the particle beam device 1. The particle beam column 39 provides the vacuum system generating the above mentioned vacuum. A first heat isolator 25 is arranged between the cooling unit 19 and the holding element 23. The first heat isolator 25 prevents the temperature of the cooling unit 19 to be influenced by the temperature of the holding element 23.

The holding element 23 has a further function. It also holds a movable aperture unit 24. The holding element 23 comprises a feed-through 26 for a motion device 27. The motion device 27 comprises a second heat isolator 28 on which the aperture unit 24 is arranged. The aperture unit 24 may be moved by the motion device 27. The aperture unit 24 may be moved along a first translational axis (for example, an x-axis), along a second translational axis (for example, a y-axis) and along a third translational axis (for example, a z-axis). Moreover, the aperture unit 24 may be rotated around a rotational axis (t-axis). A control device 40 may be used for controlling the motion device 27. The control device 40 may comprise an electrical system or an electro-pneumatic system for activating the motion device 27, and, thereby moving the aperture unit 24. This embodiment provides that the aperture unit 24 and its components (which are described below) may be manually or automatically positioned with respect to the optical axis OA and the optical path of the particle beam.

The aperture unit 24 may comprise two sub-units, namely a first aperture device 29 and a second aperture device 30. Each sub-unit may comprise at least one aperture opening. In the embodiment of FIG. 2, the first aperture device 29 comprises several aperture openings 31, and the second aperture device 30 comprises several aperture openings 32. The several aperture openings 31 may each be different in diameter. For example, the first aperture device 29 comprises three aperture openings 31; the first one may have a diameter of 25 μm, the second one may have a diameter of 40 μm, and the third one may have a diameter of 200 μm. Furthermore, the several aperture openings 32 of the second aperture device 30 may each be different in diameter. For example, the second aperture device 30 comprises three aperture openings 32; the first one may have a diameter of 10 μm, the second one may have a diameter of 30 μm, and the third one may have a diameter of 50 μm. It is explicitly mentioned that the system described herein is not restricted to the above mentioned diameters for the first aperture device 29 and the second aperture device 30. Instead, any suitable diameter may be chosen, for example a diameter in the range of 5 μm to 1000 μm, or 10 μm to 200 μm, or 20 μm to 90 μm, or 30 μm to 70 μm.

The cooling unit 19 is connected to the aperture unit 24 by two flexible thermal conductors, namely a first flexible thermal conductor 33 and a second flexible thermal conductor 34. The first flexible thermal conductor 33 is a braided copper tape. The same applies to the second flexible thermal conductor 34. The flexibility of the first flexible thermal conductor 33 and the second flexible thermal conductor 34 is advantageous with respect to the movement of the aperture unit 24 relative to the cooling unit 19. The design as a copper conductor is advantageous with respect to the heat transfer from the aperture unit 24 to the cooling unit 19. Due to the connection to the cooling unit 19, the aperture unit 24 has only a slightly different temperature than the cooling unit 19. In a further embodiment, the particle beam device 1 comprises more than two flexible thermal conductors, for example three flexible thermal conductors which connect the aperture unit 24 to the cooling unit 19. As mentioned before, the system described herein is not restricted to any particular number of flexible thermal conductors. Instead, any suitable number of flexible thermal conductors may be used. Moreover, the system described herein is not restricted to flexible thermal conductors made of copper. Instead, any suitable conducting material may be used, for example silver, gold, beryllium or a carbon composite. Moreover, the system described herein is not restricted to a braided tape as a flexible thermal conductor. Instead, at least one of the first flexible thermal conductor 33 and the second flexible conductor 34 may have any suitable form. In a further embodiment, at least one of the first flexible thermal conductor 33 and the second flexible thermal conductor 34 may be shaped as a compound spring.

The aperture unit 24 is movable next to the object 16 to be examined. The particle beam is able to pass through one of the first aperture openings 31. The particles resulting from interaction of the particle beam with the object 16 may pass through one of the second aperture openings 32 arranged next to the object 16. The system described herein described herein may have two functions. The first function may be an anticontamination function. Due to the first flexible thermal conductor 33 and the second flexible thermal conductor 34, the aperture unit 24 provides for contaminants being deposited thereon which should not be deposited on the object 16. Since the cooling unit 19 is connected to the aperture unit 24, the temperature of the aperture unit 24 is at the same temperature or nearly at the same temperature as the cooling unit 19. Therefore, contaminants are most likely to be deposited on the aperture unit 24 and the cooling unit 19. Contaminants are deposited on the object 16 only to a minor extent. For example, contamination rates may be decreased on the object 16 down to as little as 0.1 nm per hour.

The second function may be an aperture function. Due to the motion device 27, the aperture unit 24, and therefore, the first aperture openings 31 of the first aperture device 29 may be arranged with respect to the object 16 and the optical axis OA of the particle beam as desired. For example, the first aperture openings 31 of the first aperture device 29 are used as illuminating apertures for illuminating the object 16 with a focused particle beam in the scanning mode of the TEM as described before. In this case, the second aperture openings 32 of the second aperture device 30 may not be used for imaging, but only for depositing of contaminants.

Moreover, the second aperture openings 32 of the second aperture device 30 may be used as an aperture for imaging the object 16 and for impacting the contrast of an image of the object 16 using the particle beam. In this case, the first aperture openings 31 of the first aperture device 29 may not be used for imaging, but only for depositing of contaminants. Due to their size, they do not restrict the particle beam.

Therefore, the first aperture openings 31 and the second aperture openings 32 may be used for controlling, in particular, the resolution of the image of the object 16 in the scanning mode and/or for controlling the image resolution and contrast if electrons pass through the object 16 and are imaged on a final screen or a camera.

Deliberations have shown that, due to the deposition of contaminants, the diameters of the first aperture openings 31 and the second aperture openings 32 decrease rather slowly so that imaging of the object 16 is still possible. However, the cooling device 20 also comprises a heating device 35. The heating device 35 is used to heat the cooling unit 19 and, thereby the aperture unit 24. This may be done after an examination of the object 16 has ended. Heating the above mentioned units is desirable for removing contaminants being deposited on the cooling unit 19 and/or the aperture unit 24. For example, those contaminants may be removed by a pumping system (not shown).

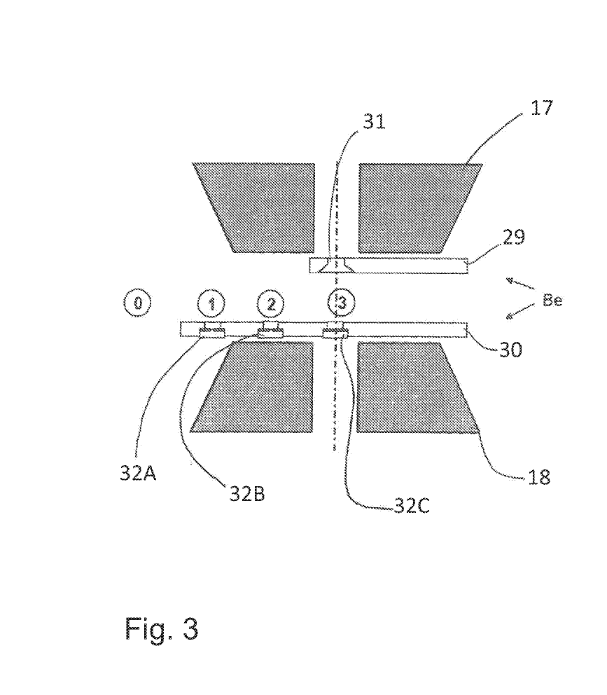

FIG. 3 shows a schematic view of the objective lens 11 of the particle beam device 1, comprising the first aperture device 29 and the second aperture device 30. The first aperture device 29 is arranged and can be moved relative to the second aperture device 30 in a step like manner along an axis which is perpendicular to the optical axis OA of the particle beam device. In this embodiment, the first aperture device 29 comprises a single first aperture opening 31. The second aperture device 30 comprises three second aperture openings 32 as mentioned above, namely a first opening 32A, a second opening 32B and a third opening 32C. The first aperture device 29 and the second aperture device 30 are made, for example, from a material having an atomic number less than 13. For example, the first aperture device 29 and the second aperture device 30 comprise beryllium or are made of beryllium. This is advantageous when the object 16 is examined by EDX using an EDX detector 36 (see FIG. 2). This avoids generating undesired X-rays when the particle beam hits the aperture unit 24. The EDX measurements of the object 16 are more accurate. As mentioned before, the system described herein is not restricted to the use of beryllium as a material for the first aperture device 29 and/or the second aperture device 30. Instead, any suitable material may be used, for example titanium or aluminium.

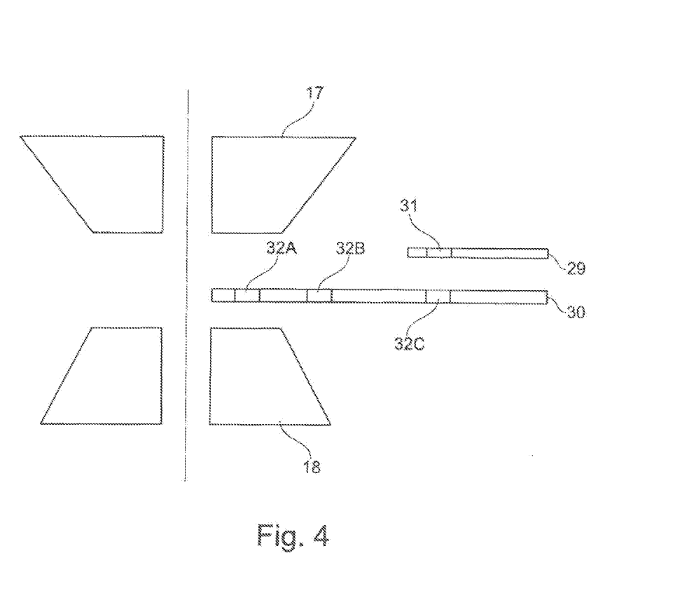

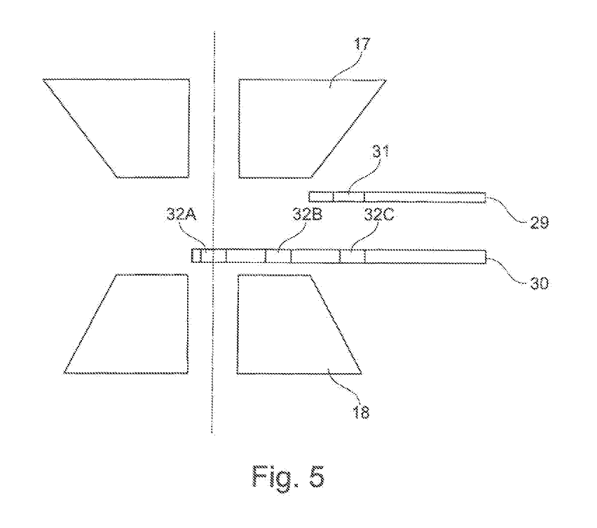

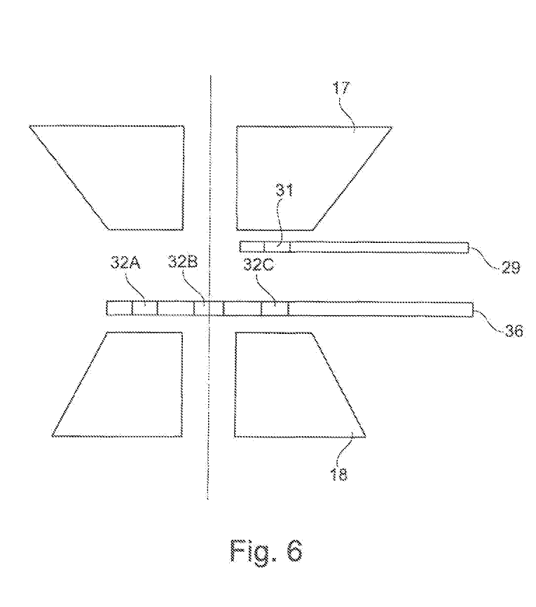

The first aperture device 29 and the second aperture device 30 of the aperture unit 24 may be moved by the motion device 27 in such a way that the first aperture device 29 and the second aperture device 30 may have several specific positions, for example four specific positions. In the first position of the first aperture device 29 and the second aperture device 30, none of the first aperture opening 31, the first opening 32A, the second opening 32B and the third opening 32C is arranged at the optical axis OA (see FIG. 4). Therefore, they are not in the optical path of the particle beam. In the second position of the first aperture device 29 and the second aperture device 30, the first opening 32A is arranged at the optical axis OA and, therefore, is in the optical path of the particle beam (see FIG. 5). The first aperture opening 31, the second opening 32B and the third opening 32C are not arranged at the optical axis OA. Therefore, they are not in the optical path of the particle beam. In the third position of the first aperture device 29 and the second aperture device 30, the second opening 32B is arranged at the optical axis OA and, therefore, is in the optical path of the particle beam (see FIG. 6). The first aperture opening 31, the first opening 32A and the third opening 32C are not arranged at the optical axis OA. Therefore, they are not in the optical path of the particle beam. In the fourth position of the first aperture device 29 and the second aperture device 30, the third opening 32C and the first aperture opening 31 are arranged at the optical axis OA and, therefore, are in the optical path of the particle beam (see FIG. 3). The first opening 32A and the second opening 32B are not arranged at the optical axis OA. Therefore, they are not in the optical path of the particle beam.

In the embodiment shown in FIG. 3, an aperture element may be arranged in each of the first opening 32A and the second opening 32B. The aperture element may be secured in the first opening 32A or in the second opening 32B by a retaining ring, for example. The aperture element may be made of beryllium. However, the system described herein is not restricted to beryllium. Instead, any suitable material may be used, for example gold, silver, platinum, iridium or any compound of these materials. The aperture element may comprise the actual aperture for the particle beam of the particle beam device 1. In a further embodiment, the aperture unit 24 may comprise an aperture element comprising several apertures. Moreover, the aperture element may comprise a ring shaped aperture device.

Various embodiments discussed herein may be combined with each other in appropriate combinations in connection with the system described herein. Additionally, in some instances, the order of steps in the flowcharts, flow diagrams and/or described flow processing may be modified, where appropriate. Further, various aspects of the system described herein may be implemented using software, hardware, a combination of software and hardware and/or other computer-implemented modules or devices having the described features and performing the described functions. Software implementations of the system described herein may include executable code that is stored in a computer readable medium and executed by one or more processors. The computer readable medium may include volatile memory and/or non-volatile memory, and may include, for example, a computer hard drive, ROM, RAM, flash memory, portable computer storage media such as a CD-ROM, a DVD-ROM, a flash drive and/or other drive with, for example, a universal serial bus (USB) interface, and/or any other appropriate tangible or non-transitory computer readable medium or computer memory on which executable code may be stored and executed by a processor. The system described herein may be used in connection with any appropriate operating system.

Other embodiments of the invention will be apparent to those skilled in the art from a consideration of the specification or practice of the invention disclosed herein. It is intended that the specification and examples be considered as exemplary only, with the true scope and spirit of the invention being indicated by the following claims.

1. An apparatus for contaminants being deposited thereon in a particle beam device, comprising:
at least one cooling unit;
at least one aperture unit; and
at least one motion device for moving said aperture unit relative to the cooling unit, wherein said aperture unit is arranged at the motion device, wherein said aperture unit has at least one aperture opening, and wherein said cooling unit is connected to said aperture unit by at least one first flexible thermal conductor.

2. The apparatus according to claim 1, wherein said cooling unit is exclusively connected to said aperture unit by said at least one first flexible thermal conductor, and wherein said cooling unit is otherwise entirely spatially separated from said aperture unit.

3. The apparatus according to claim 1, further comprising at least one of the following features:
(i) said aperture unit is movable along at least one first translational axis,
(ii) said aperture unit is movable along at least one second translational axis,
(iii) said aperture unit is movable along at least one third translational axis, or
(iv) said aperture unit is rotatable around at least one rotational axis.

4. The apparatus according to claim 1, wherein a thermal isolator is arranged between said aperture unit and said motion device.

5. The apparatus according to claim 1, wherein said cooling unit comprises at least one cooling surface for contaminants being deposited thereon, wherein said cooling surface is connected to a cooling device, and wherein a container for holding a cooling solvent is arranged at said cooling device.

6. The apparatus according to claim 5, wherein said cooling solvent is a cryogen.

7. The apparatus according to claim 1, wherein said cooling unit comprises at least one first cooling surface unit and at least one second cooling surface unit, said first cooling surface unit is connected to a cooling device, and wherein a container for holding a cooling solvent is arranged at said cooling device.

8. The apparatus according to claim 7, wherein said cooling solvent is a cryogen.

9. The apparatus according to claim 1, wherein said cooling unit is connected to said aperture unit additionally by at least one second flexible thermal conductor.

10. The apparatus according to claim 1, further comprising at least one of the following:
(i) said first flexible thermal conductor is a braided tape, or
(ii) said first flexible thermal conductor is a copper conductor.

11. The apparatus according to claim 9, further comprising at least one of the following:
(i) said second flexible thermal conductor is a braided tape, or
(ii) said second flexible thermal conductor is a copper conductor.

12. The apparatus according to claim 1, wherein said aperture unit comprises at least one first aperture device and at least one second aperture device, wherein said first aperture device has at least one first aperture opening, wherein said second aperture device has at least one second aperture opening, and wherein said first aperture device is separated from said second aperture device with a distance between said first aperture device and said second aperture device.

13. The apparatus according to claim 12, wherein said first aperture device is moveable relative to said second aperture device in a step-like manner.

14. The apparatus according to claim 12, further comprising at least one of the following features:
(i) said first aperture opening is an aperture for imaging of an object with a particle beam;
(ii) said second aperture opening is an aperture for imaging of an object with a particle beam;
(iii) said first aperture opening is an aperture for illuminating an object with a particle beam; or
(iv) said second aperture opening is an aperture for illuminating an object with a particle beam.

15. The apparatus according to claim 1, further comprising at least one of the following features:
(i) said aperture unit is made at least partially from a material having an atomic number less than 13 or equal to 13, or
(ii) said aperture unit comprises beryllium.

16. A particle beam device, comprising:
at least one beam generator for generating a particle beam;
at least one holding element for holding an object;
at least one objective lens for imaging or focussing said particle beam; and
at least one apparatus for contaminants being deposited thereon, wherein said apparatus comprises at least one cooling unit, at least one aperture unit, and at least one motion device for moving said aperture unit relative to said cooling unit, wherein said aperture unit is arranged at the motion device, wherein said aperture unit has at least one aperture opening, and wherein said cooling unit is connected to said aperture unit by at least one first flexible thermal conductor.

17. The particle beam device according to claim 16, wherein said apparatus is arranged in the objective lens.

18. The particle beam device according to claim 16, further comprising one of the following:
(i) said motion device is arranged at a flange, wherein said flange is arranged on a vacuum chamber;
(ii) said aperture unit and said motion device are arranged at a flange, wherein said flange is arranged on a vacuum chamber;
(iii) said cooling unit and said motion device are arranged at a flange, wherein said flange is arranged on a vacuum chamber; or
(iv) said cooling unit, said motion device and said aperture unit are arranged at a flange, wherein said flange is arranged on a vacuum chamber.

19. The particle beam device according to claim 16, further comprising:
a cooling system for cooling an object.

20. The particle beam device according to claim 16, wherein said particle beam device is an electron beam device or an ion beam device.

21. An apparatus for contaminants being deposited thereon in a particle beam device, comprising:
at least one cooling unit;
at least one aperture unit; and
at least one motion device for moving said aperture unit relative to the cooling unit, wherein said aperture unit is arranged at the motion device, wherein said aperture unit has at least one aperture opening, and wherein said cooling unit is directly connected to said aperture unit by at least one first flexible thermal conductor.

22. A particle beam device, comprising:
at least one beam generator for generating a particle beam;
at least one holding element for holding an object;
at least one objective lens for imaging or focusing said particle beam; and
at least one apparatus for contaminants being deposited thereon, wherein said apparatus comprises at least one cooling unit, at least one aperture unit, and at least one motion device for moving said aperture unit relative to said cooling unit, wherein said aperture unit is arranged at the motion device, wherein said aperture unit has at least one aperture opening, and wherein said cooling unit is directly connected to said aperture unit by at least one first flexible thermal conductor.

23. An apparatus for contaminants being deposited thereon in a particle beam device, comprising:
at least one cooling unit;
at least one aperture unit; and
at least one motion device for moving said aperture unit relative to the cooling unit, wherein said aperture unit is arranged at the motion device, wherein said aperture unit has at least one aperture opening, and wherein at least one first flexible thermal conductor is arranged at said cooling unit and said aperture unit.

24. A particle beam device, comprising:
at least one beam generator for generating a particle beam;
at least one holding element for holding an object;
at least one objective lens for imaging or focusing said particle beam; and
at least one apparatus for contaminants being deposited thereon, wherein said apparatus comprises at least one cooling unit, at least one aperture unit, and at least one motion device for moving said aperture unit relative to said cooling unit, wherein said aperture unit is arranged at the motion device, wherein said aperture unit has at least one aperture opening, and wherein at least one first flexible thermal conductor is arranged at said cooling unit and said aperture unit.
